(19) United States
(12) Patent Application Publication
(10) Pub. No.: US 2012/0316815 A1
(43) Pub. Date: Dec. 13, 2012

(54) METHOD FOR EVALUATING DETERIORATION OF LITHIUM ION SECONDARY BATTERY, AND BATTERY PACK

(76) Inventor: Kenichi Morigaki, Hyogo (JP)

(21) Appl. No.: 13/579,221

(22) PCT Filed: Nov. 4, 2011
(86) PCT No.: PCT/JP2011/006175

§ 371 Date: Aug. 15, 2012

(30) Foreign Application Priority Data
Jan. 14, 2011 (JP) 2011-005583

(51) Int. Cl. G01R 31/36; G06F 19/00; G01N 27/416

(52) U.S. Cl. 702/63; 324/430

(57) ABSTRACT

Disclosed is a method for evaluating deterioration of a lithium ion secondary battery, in which an impedance spectrum of a lithium ion secondary battery is measured using alternating current of a predetermined frequency range. In a diagram including an arc-like portion obtained when the impedance spectrum is represented on a complex plane defined by a resistive component axis and a capacitive component axis, the coordinates of a peak of the arc-like portion are determined. The deterioration state of the lithium ion secondary battery is evaluated on the basis of the determined coordinates of the peak.

### TECHNICAL FIELD

The present invention relates to a method for evaluating the deterioration state of a lithium ion secondary battery by utilizing an impedance spectrum, and a battery pack to which the same is applied.

### BACKGROUND ART

Lithium ion secondary batteries are widely used as a power source for small-sized consumer electronics such as cellular phones and personal computers. In recent years, they are expected to be used also as a vehicle-mounted power source for electric vehicles, hybrid electric vehicles, etc., or a power source for a stationary power-generating device to be used in combination with a power generating system such as a photovoltaic power generating system or a wind energy conversion system.

The electrode active materials generally used for lithium ion secondary batteries are, in the positive electrode, a lithium-containing composite oxide such as lithium cobalt oxide or lithium nickel oxide, and in the negative electrode, a carbon material such as graphite. The life of the lithium ion secondary batteries including these electrode active materials is usually about 5 to 10 years.

In general, in most of the small-sized consumer electronics, which have a product life of 2 to 5 years, the cases are rare where deterioration of the lithium ion secondary battery becomes a problem. However, in equipment having a product life longer than the battery life, or equipment used in an environment in which battery deterioration tends to be accelerated, there is a possibility that the battery deterioration shortens the length of time for which the equipment can be used on one charge, or causes the equipment to fail to function as designed.

Particularly in a large-sized power supply for vehicle-mounted use, several tens to hundreds batteries are sometimes used, and in many cases, the batteries are connected in series. As such, deterioration of only one of these batteries, if any, will possibly affect the performance of the entire power supply. In this case, the deterioration of the one battery might cause the equipment to fail to function normally as designed. There is a demand, therefore, for development of a technique that makes possible an easy and accurate detection of the deterioration state of the battery.

In response to such demand, Patent Literature 1 proposes diagnosing the deterioration of a lithium ion secondary battery, on the basis of a capacity reduction rate detected when the lithium ion secondary battery is charged or discharged at a current corresponding to, or example, an 8 to 10 hour rate, and a capacity reduction rate detected when the lithium ion secondary battery is charged or discharged at a current corresponding to, or example, a 30 to 50 hour rate.

Patent Literature 2 proposes, in order to judge the deterioration state of a battery for vehicle-mounted use (a lead-acid battery), detecting the internal impedance of the battery.

Patent Literature 3 proposes detecting the state of a lithium ion secondary battery, on the basis of an input/output phase difference measured when an alternating current (AC) signal having a specific frequency is input to the lithium ion secondary battery.

### CITATION LIST

### Patent Literature

[PTL 1] Japanese Laid-Open Patent Publication No. 2003-308885
[PTL 2] Japanese Laid-Open Patent Publication No. 2007-85772
[PTL 3] Japanese Laid-Open Patent Publication No. 2009-244088

### SUMMARY OF INVENTION

### Technical Problem

According to the technique disclosed in Patent Literature 1, in order to judge the deterioration state of a lithium ion secondary battery, for example, the capacity reduction rate at 8 to 10 hour rate, and at 30 to 50 hour rate must be determined. As such, it takes a long time to acquire the data to be the basis of judgment on the deterioration state.

The acquisition of such data is possible, of course, in a laboratory. However, as for a lithium ion secondary battery used as a power source in actual equipment, the acquisition of such data is possible only on limited occasions. For this reason, it appears difficult to put the technique disclosed in Patent Literature 1 into practical use.

The technique disclosed in Patent Literature 2 is for detecting deterioration of a lead-acid battery whose deterioration is closely related to depletion of electrolyte. To a secondary battery including an aqueous solution-type electrolyte, such as a lead-acid battery, the technique disclosed in Patent Literature 2 might be applicable as an effective deterioration evaluation method. However, in a non-aqueous electrolyte secondary battery, such as a lithium ion secondary battery, the main cause for deterioration is different from that in a lead-acid battery. Therefor, there is a case where the deterioration state of a lithium ion secondary battery cannot be evaluated with sufficient accuracy by the method disclosed in Patent Literature 2.

The technique disclosed in Patent Literature 3 detects the state of a lithium ion secondary battery, on the basis of an input/output phase difference of an AC signal having a specific frequency. As such, the deterioration state of a lithium ion secondary battery might be diagnosed very easily.

However, the response when an AC signal is input to a lithium ion secondary battery is susceptible to influence of the capacity, temperature, and state of charge (SOC) of the battery. Accordingly, the input/output phase difference includes the influence of the capacity, temperature, and SOC of the battery. As such, if the input/output phase difference is used directly for judging the deterioration state, the quantitative capability of the judgment criteria for deterioration is reduced, and it might become impossible to judge the degree of deterioration of a lithium ion secondary battery with sufficient accuracy.

In view of the above, the present invention intends to provide a means for enabling a judgment on the deterioration state of a lithium ion secondary battery with sufficient accuracy in a simple and easy manner.

### Solution to Problem

One aspect of the present invention relates to a method for evaluating deterioration of a lithium ion secondary battery, the method comprising the steps of:

measuring an impedance spectrum of a lithium ion secondary battery, using alternating current of a predetermined frequency range,

determining coordinates of a peak of an arc-like portion, when the impedance spectrum is represented by a diagram including the arc-like portion on a complex plane defined by a resistive component axis and a capacitive component axis, and

evaluating a deterioration state of the lithium ion secondary battery, on the basis of the coordinates.

Another aspect of the present invention relates to a battery pack comprising

at least one lithium ion secondary battery,

a charging circuit for charging the lithium ion secondary battery with externally supplied power,

a discharging circuit for externally discharging power stored in the lithium ion secondary battery,

a controller for controlling the charging circuit and the discharging circuit,

a measurement unit for measuring an impedance spectrum of the lithium ion secondary battery by an alternating current impedance method, and

an evaluation unit for evaluating a deterioration state of the lithium ion secondary battery, on the basis of the measurement result of the measurement unit, wherein

the evaluation unit
determines coordinates of a peak of an arc-like portion, when the impedance spectrum is represented by a diagram including the arc-like portion on a complex plane defined by a resistive component axis and a capacitive component axis, and
evaluates the deterioration state of the lithium ion secondary battery on the basis of the coordinates.

### Advantageous Effects of Invention

According to the method for evaluating deterioration of a lithium ion secondary battery and the battery pack of the present invention, the deterioration state of a lithium ion secondary battery can be judged with sufficient accuracy in a simple and easy manner.

While the novel features of the invention are set forth particularly in the appended claims, the invention, both as to organization and content, will be better understood and appreciated, along with other objects and features thereof, from the following detailed description taken in conjunction with the drawings.

### BRIEF DESCRIPTION OF DRAWING

FIG. 1 A block diagram showing a schematic configuration of a deterioration evaluation apparatus to which a method for evaluating deterioration of a lithium ion secondary battery according to one embodiment of the present invention is applied.

FIG. 2 A Nyquist diagram of an exemplary impedance spectrum of a lithium ion secondary battery.

FIG. 3 A graph showing frequency characteristics of an angle 8 of other exemplary impedance spectra of a lithium ion secondary battery.

FIG. 4 A function block diagram showing a schematic configuration of a battery pack according to another embodiment of the present invention.

FIG. 5 A graph showing a relationship between the output retention rate and the tan θ of the impedance spectrum of the lithium ion secondary battery of each Example of the present invention.

### DESCRIPTION OF EMBODIMENTS

The present invention relates to a method in which the frequency characteristics of the impedance of a lithium ion secondary battery are analyzed by an alternating current (AC) impedance method, and the deterioration state of the lithium ion secondary is evaluated on the basis of the analyzed frequency characteristics.

In this method, the impedance spectrum of a lithium ion secondary battery is measured using alternating current of a predetermined frequency range. When the measured impedance spectrum is represented by a diagram including an arc-like portion on a complex plane defined by a resistive component axis (Z′ axis, the real axis) and a capacitive component axis (Z″ axis, the imaginary axis), the coordinates of a peak of the arc-like portion are determined. On the basis of the determined coordinates of the peak, the deterioration state of the lithium ion secondary battery is evaluated. For example, when the coordinates of the peak are denoted by (Z′, Z″), the deterioration state of the lithium ion secondary battery can be evaluated on the basis of a ratio |Z″|/Z′, as described below. Alternatively, for example, from the coordinates of the peak, a straight line passing through the peak and the origin of the complex plane is determined, and an angle θ between the straight line and the resistive component axis is determined. The deterioration state of the lithium ion secondary battery can be evaluated on the basis of the determined angle θ.

One of the problems to be solved for prolonging the life of a lithium ion secondary battery is to suppress the deterioration in power output or power generation of the lithium ion secondary battery. An experimental result shows that, in the case where the lithium ion secondary battery includes a certain type of lithium-containing composite oxide as a positive electrode material, the degree of deterioration in power output (the increase rate of direct current (DC) internal resistance) is several times as high as the degree of deterioration in capacity under predetermined conditions. In this case, the main factor for determining the battery life is not the deterioration in capacity but the deterioration in power output. As such, in this case, suppressing an increase in the internal resistance of the lithium ion secondary battery is effective in prolonging the life of the lithium ion secondary battery.

As described above, the internal resistance of a lithium ion secondary battery is one of primary parameters relating to the deterioration state of the lithium ion secondary battery. The internal resistance of a lithium ion secondary battery, however, includes a capacitive component, and, therefore, in order to accurately evaluate the deterioration state thereof, it is necessary to precisely measure the internal resistance, including the capacitive component, by, for example, an AC impedance method.

In the case of measuring the impedance of an electrochemical cell such as a lithium ion secondary battery by an AC impedance method, the frequency characteristics of the impedance are analyzed using an equivalent circuit model of battery. More specifically, the electronic resistance and the separator of the battery are regarded as forming a parallel circuit of the resistance and the capacity. Alternatively, the total ionic resistance of the electrolyte and the positive and negative electrodes are regarded as forming a parallel circuit of the resistance and the capacity. In this way, an equivalent circuit model of a whole battery is derived.

Next, alternating current of various frequencies is applied to the battery, and the response thereto is analyzed, to determine the parameters of the equivalent circuit of the battery.

A graph in which the frequency characteristics determined through such analysis are represented as a diagram (Nyquist diagram) on a complex plane is generally called a Cole-Cole plot.

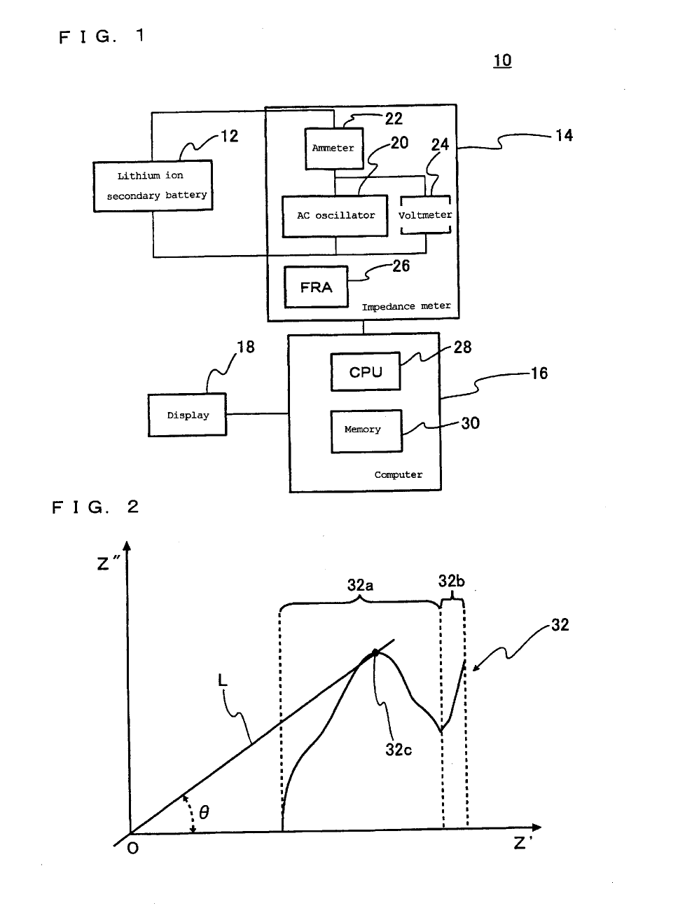

The Cole-Cole plot of a lithium ion secondary battery generally includes an arc-like portion which starts from a point near the origin, and a straight line portion which continues obliquely upward from the end point of the arc-like portion (see FIG. 2).

It should be noted that the parameters of the equivalent circuit of the electrode (positive or negative electrode) vary greatly depending on the area of the sheet-like electrode and the amount of the active material filled therein. The parameters of the equivalent circuit of a whole battery also vary greatly depending on the capacity and output characteristics of the battery. As a result, the arc-like portions of the Cole-Cole plots of batteries having different capacities and output characteristics become different in shape and size. Therefore, actually, it is difficult to directly use the analysis results obtained by an AC impedance method for evaluating the deterioration states of batteries having various capacities.

In the method of the present invention, the impedance spectrum is measured using alternating current of a predetermined frequency range, and the coordinates of a peak of an arc-like portion are determined, when the impedance spectrum is represented by a diagram including the arc-like portion on a complex plane. Then, for example, a straight line passing through the peak and the origin of the complex plane is determined. Further, an angle θ (0<θ<90° between the straight line and the horizontal axis (the resistive component axis, Z′ axis) of the complex plane is determined, and the deterioration state of the lithium ion secondary battery is evaluated on the basis of the angle θ.

The present inventor has conducted detailed studies on the impedance spectra of lithium ion secondary batteries having variously different levels of deterioration in power output. As a result, it has been verified that, among lithium ion secondary batteries having various shapes and capacities, there is a quantitatively close correlation between the angle θ and the output deterioration state (see FIG. 5).

Therefore, by using the angle θ as a basis for evaluating the deterioration state of a lithium ion secondary battery, the analysis results obtained by an AC impedance method can be standardized. As a result, evaluation of the deterioration states of lithium ion secondary batteries having various shapes and capacities becomes possible by using only one parameter: θ.

The present invention encompasses evaluation of the deterioration state of a lithium ion secondary battery using a parameter that can be uniquely derived from the angle θ being an acute angle, or alternatively, using a parameter equivalent thereto.

One example of such a parameter is a tangent of the angle θ: tan θ. Another example thereof is a ratio |Z″|/Z′ derived from components, Z′ and |Z″|, of the impedance Z (=Z′−Z″j) corresponding to the peak, or from the coordinates (Z′, Z″) of the peak. This is based on “tan θ=|Z″|/Z′”. Besides, a sine or cosine of the angle θ, i.e., sin θ or cos θ, may be used as the parameter. Here, Z′ is a resistive component of the impedance Z, Z″ is a capacitive component of the impedance Z, and j is the imaginary unit.

As describe above, in one embodiment of this method, the angle θ or tan θ or ratio |Z″|/Z′ is calculated, and on the basis of the calculated angle θ or the like, the deterioration state of a lithium ion secondary battery is evaluated. From FIG. 5, it can be easily inferred that there is a close correlation which can be approximated by a simpler equation, between the tan θ and the deterioration state of a lithium ion secondary battery (here, the output retention rate measured after a predetermined charge/discharge cycle processing). Therefore, by using the tan θ or ratio |Z″|/Z′ instead of directly using the angle θ, the deterioration state of a lithium ion secondary battery can be evaluated more easily and accurately.

The frequency range of alternating current used when measuring an impedance spectrum of a lithium ion secondary battery is preferably from 0.1 to 30 Hz. In a high frequency range, the difference in the area of the electrode, i.e., the difference in the shape and capacity of the battery, might have a significant influence on the analysis results. Consequently, the influence due to the difference in the area of the electrode etc. might be reflected on the angle θ and tan θ. The studies by the present inventor have verified that in a low frequency range, for example, from 0.1 to 30 Hz, the influence due to such difference on the impedance spectrum is small. Therefore, by using the analysis results obtained in the above frequency range, a more accurate evaluation of the deterioration state of a lithium ion secondary battery becomes possible. It should be noted that the lower limit fb of 0.1 Hz of the above frequency range may be changed within the range, for example, 0.01≦fb≦0.5 (Hz). The upper limit fu of 30 Hz of the above frequency range may be changed within the range, for example, 10≦fu≦50 (Hz).

The positive electrode of a lithium ion secondary battery may include, as an active material, a composite oxide containing lithium and a transition metal. Examples of the composite oxide include a composite oxide containing lithium and cobalt (LiCoO₂), a composite oxide containing lithium and nickel (LiNiO₂), or a composite oxide containing lithium and manganese (LiMn₂O₄). To the composite oxide containing lithium and cobalt, a transition metal element, such as nickel, iron, manganese, titanium, zirconium, vanadium, niobium, chromium, molybdenum and copper; and a typical element, such as aluminum, magnesium, boron, calcium and strontium, may be added. To the composite oxide containing lithium and nickel, at least one selected from the group consisting of the above-listed elements (except nickel) and cobalt may be added. To the composite oxide containing lithium and manganese, at least one of the above-listed elements (except manganese) may be added. In order to achieve a higher output and higher capacity of the battery, it is preferable to use a composite oxide containing lithium and nickel to which cobalt and aluminum are added, as a positive electrode active material.

Among these positive electrode active materials, lithium cobalt oxide (LiCoO₂), which exhibits a discharge potential as high as 4 V and a highly stable performance is usually used as a positive electrode active material in lithium ion secondary batteries for small-sized consumer electronics. However, cobalt is rare, and by using it, the costs are increased. Therefore, as an alternative to using a lithium cobalt oxide, using a composite oxide containing lithium and nickel as a positive electrode active material has been attracting interest.

However, when the positive electrode active material comprises a composite oxide containing lithium and nickel, the lithium-ion diffusion resistance tends to increase as the charge and discharge are repeated. For this reason, the life of a battery including such a composite oxide as a positive electrode active material tends to be dependent on the degree of deterioration not in capacity but in output. The deterioration state of such a battery, in particular, can be judged more properly by applying the present invention thereto.

The negative electrode of a lithium ion secondary battery of the present invention includes, as an active material, a material capable of charging and releasing lithium ions. Such a material is exemplified by a carbon material, a Si alloy, or a Si oxide. Examples of the carbon material include artificial graphite, natural graphite, petroleum coke, carbon coke, phenol resin carbide, pitch-based carbon fibers, and PAN-based carbon fibers. Alternatively, a composite material comprising two or more carbon materials may be used.

The present invention further relates to a battery pack including at least one lithium ion secondary battery, a charging circuit for charging the lithium ion secondary battery with externally supplied power, a discharging circuit for externally discharging power stored in the lithium ion secondary battery, and a controller for controlling the charging circuit and the discharging circuit.

This battery pack includes a measurement unit for measuring an impedance spectrum of the lithium ion secondary battery by an AC impedance method, and an evaluation unit for evaluating the deterioration state of the lithium ion secondary battery, on the basis of the measurement result of the measurement unit.

The evaluation unit determines the coordinates of a peak of an arc-like portion, when the measured impedance spectrum is represented by a diagram including the arc-like portion on a complex plane defined by a resistive component axis and a capacitive component axis, and evaluates the deterioration state of the lithium ion secondary battery on the basis of the coordinates.

The slope (|Z″|/Z′) of a straight line passing through the peak of the arc-like portion and the origin of the complex plane can be represented by “tan θ”, when the angle between the straight line and the resistive component axis is denoted by “θ”. Given that the impedance Z corresponding to the peak of the arc-like portion is determined, the deterioration state of the lithium ion secondary battery can be evaluated by, for example, calculating the ratio |Z″|/Z′ of the resistive component to the capacitive component of the impedance Z, and using the ratio as a basis for evaluation as described above. The evaluation result is stored, for example, as an electrical signal in a predetermined storing place.

Now referring to the drawings appended hereto, a schematic configuration of a deterioration evaluation apparatus to which a method for evaluating deterioration of a lithium ion secondary battery according to one embodiment of the present invention is applied is shown by way of a function block diagram.

A deterioration evaluation apparatus 10 shown in the drawing includes an impedance meter 14 for measuring an impedance spectrum of a lithium ion secondary battery (hereinafter simply referred to as a “battery”) 12, a computer 16 for executing a predetermined processing for evaluating the deterioration state of a lithium ion secondary battery, with respect to the measured impedance spectrum, a display 18 for displaying the results processed by the computer 16.

The impedance meter 14 includes an AC oscillator 20 for generating alternating current of a predetermined frequency to be applied to the lithium ion secondary battery 12, an ammeter 22 and a voltmeter 24 for monitoring the voltage and current of the alternating current, and a frequency response analyzer (FRA) 26.

The computer 16 has a central processing unit (CPU) 28 and a memory 30. The CPU 28 performs the below-described processing. The memory 30 stores the below-described data.

In the case of measuring an electrochemical impedance of the lithium ion secondary battery 12 under potentiostatic polarization, a predetermined potential E_{DC} is set, and a potential signal (E_{DC}+ΔE_{OSC}) obtained by superimposing on the E_{DC}, an AC signal ΔE_{OSC} of a predetermined frequency generated from the AC oscillator 20 is applied to, for example, the positive electrode of a lithium ion secondary battery. The current response (I_{DC}+ΔIᵣₑₛ) to the potential signal (E_{DC}+ΔE_{OSC}) is measured with the ammeter 22. The potential signal (E_{DC}+ΔE_{OSC}) is hereinafter referred to as an input signal.

To the frequency response analyzer 26, the input signal (E_{DC}+ΔE_{OSC}), and a potential signal R_{range}(I_{DC}+ΔIᵣₑₛ) obtained by passing the current response (I_{DC}+ΔIᵣₑₛ) through a predetermined resistance R_{range} are input. The potential signal R_{range}(I_{DC}+ΔIᵣₑₛ) is hereinafter referred to as a response signal.

The frequency response analyzer 26, for example, converts the AC components of the input signal and the response signal into frequency-domain data by using discrete Fourier transform, and calculates the ratio between the data, to determine a dimensionless impedance Z_{bar}(ω) at the frequency of the AC signal ΔE_{OSC}, as shown in the equation below (1).

Z_{bar}(ω)=FT{ΔE_{osc}/FT{R}_{range}×ΔIᵣₑₛ} (1),

where FT{ } represents an operation by discrete Fourier transform, and ω is an angular frequency.

Next, by multiplying the above resistance R_{range} by Z_{bar}(ω) as shown in the equation (2) below, an impedance Z(ω) at the frequency said above can be obtained.

Z(ω)=R_{range}×Z_{bar}(ω) (2).

Subsequently, the frequency of the alternating current applied is swept through a predetermined frequency range, to measure an impedance spectrum. The frequency range used for measuring an impedance spectrum is preferably set to 0.1 to 30 Hz, because the influence of the area of the electrodes (positive and negative electrodes) can be reduced. It should be noted that the lower limit fb of 0.1 Hz of the above frequency range may be changed within the range, for example, 0.01≦fb≦0.5 (Hz). The upper limit fu of 30 Hz of the above frequency range may be changed within the range, for example, 10≦fu≦50 (Hz).

The CPU 28 draws a Cole-Cole plot (Nyquist diagram) by plotting the impedance spectrum measured in the impedance meter 14 on a complex plane defined by a resistive component axis (Z′ axis, the real axis) and a capacitive component axis (Z″ axis, the imaginary axis).

FIG. 2 shows an exemplary Cole-Cole plot of an impedance spectrum of a lithium ion secondary battery. As shown in the figure, a Cole-Cole plot 32 in this case includes an arc-like portion 32a which starts from a point near the origin and a straight line portion 32b which continues obliquely upward from the end point of the arc-like portion 32a.

The CPU 32 then determines a straight line L passing through a peak 32c of the arc-like portion 32a and the origin O of the complex plane, and determines an angle θ between the straight line L and the Z′ axis, to calculate a tangent of the angle θ: tan θ. The calculated tan θ is collated with the data used for judging deterioration state and stored in the memory 30, whereby the deterioration state of the lithium ion secondary battery is evaluated. For example, an increase rate of DC internal resistance in the lithium ion secondary battery from that of the initial state is calculated. The data used for judging the deterioration state in this case are data obtained in search for a relationship between the tan θ and the output deterioration state at a predetermined state of charge (SOC), by using another lithium ion secondary battery whose positive and negative electrodes have the same compositions as those of the lithium ion secondary battery 12 to be subjected to evaluation. The “SOC” as used herein is an index to show a ratio of electrical energy stored in the battery, when the ratio in a fully charged state at the nominal capacity is expressed as 100% and the ratio in a fully discharged state at the nominal capacity is expressed as 0%.

It should be noted that the CPU 28 need not actually draw a Cole-Cole plot. If an impedance Z (=Z′−Z″j) corresponding to the peak of the arc-like portion 32a is identified, the angle θ and tan θ can be directly determined from the components, Z′ and Z″, of the impedance Z. Alternatively, the coordinates of the peak (Z′, Z″) of the arc-like portion 32a can be determined, from which a ratio |Z″|/Z′ can be determined. For example, in the case where a frequency range corresponding to the arc-like portion 32a can be predicted, the angle θ and tan θ can be determined by determining an impedance Z that gives a largest capacitive component in the frequency range.

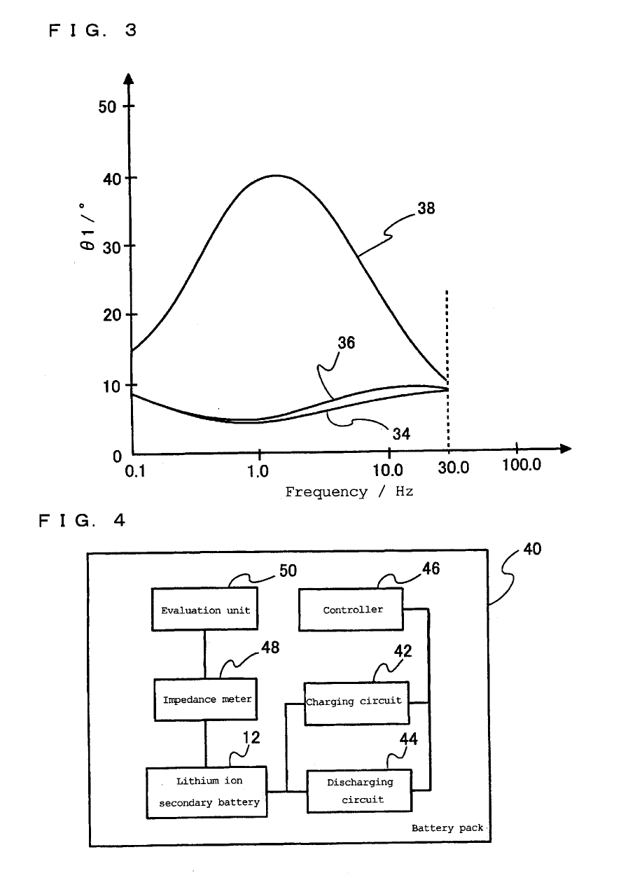

FIG. 3 shows the results with respect to lithium ion secondary batteries in various deterioration states, obtained by determining a straight line passing through each plotted point on the Cole-Cole plot and the origin, in the frequency range from 0.1 to 30 Hz, and determining an angle θ1 between the straight line and the Z′ axis. The horizontal axis in FIG. 3 is a logarithmic frequency axis. The vertical axis of the graph represents the angle θ1.

A curve 34 corresponds to a lithium ion secondary battery exhibiting almost no deterioration, a curve 36 corresponds to a lithium ion secondary battery in a deterioration state of 15%, and a curve 38 corresponds to a lithium ion secondary battery in a deterioration state of 69%. As the measure of the deterioration state (%), an increase rate of DC internal resistance of the lithium ion secondary battery from that of the initial state may be used.

As shown in FIG. 3, the higher the deterioration state of the lithium ion secondary battery is, the more evident the peak appears on the curve. This means that the higher the deterioration state of the lithium ion secondary battery is, the more evident the arc-like portion 32a and the peak thereof appear. On the other hand, when no evident peak of the arc-like portion 32a is observed in the frequency range from 0.1 to 30 Hz, it can be judged that there is little or no deterioration in the battery.

FIG. 5 is a graph showing a relationship between the tan θ and the output retention rate of the lithium ion secondary batteries of the below-described Examples. The output retention rate is that measured using batteries in a 30% SOC.

For example, the battery output at 30% SOC can be determined by: dividing the difference in voltage between an open-circuit voltage (OCV) at 30% SOC and an end-of-discharge voltage (e.g., 2.5 V) by the DC internal resistance, to determine a current value; and multiplying the determined current value by the end-of-discharge voltage. Provided that the OCV of the battery at 30% SOC remains unchanged even if the battery is deteriorated, the output of the deteriorated battery can be easily determined from the DC internal resistance or the inverse thereof. Hence, for example, when the DC internal resistance of the lithium ion secondary battery above is denoted by R1, and the DC internal resistance of the lithium ion secondary battery in an initial state is denoted by R2, the output retention rate can be calculated from the formula: (R2/R1)×100(%).

FIG. 5 indicates the presence of a very close correlation between the tan θ or the ratio |Z″|/Z′ and the output retention rate of the lithium ion secondary battery. Therefore, by determining the tan θ, the deterioration state of a lithium ion secondary battery can be evaluated accurately. For example, the increase rate of DC internal resistance from that of the initial state can be determined accurately.

The frequency range used for measuring an impedance spectrum of a lithium ion secondary battery is preferably set to from 0.1 to 30 Hz. If the impedance spectrum is measured in a frequency range extending below 0.1 Hz, the measurement takes a longer time. On the other hand, if it is measured in a frequency range extending above 30 Hz, the impedance spectrum is influenced by the shape and capacity of the battery, and the tan θ may reflect the influence.

Further, the impedance spectrum of a lithium ion secondary battery is strongly influenced by the SOC and the ambient temperature. For example, the impedance of a lithium ion secondary battery tends to increase in a low temperature environment, and decrease in a high temperature environment. For this reason, in order to obtain more highly quantified data, it is preferable to set reference values of the SOC and ambient temperature and measures an impedance spectrum under the set conditions.

The SOC at the time of the measurement is preferably within ±5% of the reference value. The ambient temperature at the time of the measurement is preferably within ±2° C. of the reference value. A preferable range of the SOC for measuring an impedance spectrum is from 20% to 80%. Particularly when the battery includes a positive electrode including a composite oxide containing nickel and lithium, the impedance spectrum when the SOC is less than 20% gives a Cole-Cole plot in which the proportion of the arc-like portion 32a is very large, which makes the deterioration judgment difficult.

A preferable range of the ambient temperature for measuring an impedance spectrum is from 20 to 40° C. In measuring an impedance spectrum, the battery temperature is preferably as uniform as possible into the interior of the battery. If the measurement is performed at an ambient temperature below 20° C. or above 40° C., the difference between the ambient temperature at the time of the measurement and the room temperature might be increased. As a result, the temperature of the battery at or near its surface might become significantly different from that in its interior.

As such, for example, in the case of a large-sized battery, it will take a long time for the battery temperature becomes uniform throughout the battery, which means that the time taken for preparing favorable conditions for measuring an impedance spectrum will be prolonged. However, in the case where a sufficient time can be afforded to measure an impedance spectrum, the deterioration state of a lithium ion secondary battery can be evaluated more accurately using an impedance spectrum measured over a wider temperature range, as shown in the below-described Examples.

One exemplary method of producing the lithium ion secondary battery 12 is described below.

A positive electrode active material, a conductive material, and a binder are mixed, and a dispersion medium is added to the resultant mixture, to form a paste. The paste is applied onto a surface of a positive electrode current collector, and dried, whereby a positive electrode precursor with a positive electrode material mixture layer formed thereon is obtained. The precursor is rolled, and then cut in a predetermined size, whereby a positive electrode for a lithium ion secondary battery is obtained.

The positive electrode active material is as described above. The conductive material for the positive electrode may be a carbon material such as artificial graphite or carbon black, or a mixture of two carbon materials. The binder may be a fluorocarbon resin, such as polytetrafluoroethylene, polyvinylidene fluoride, hexafluoropropylene-tetrafluoroethylene copolymer, and fluorine-based rubber; a thermoplastic resin, such as polypropylene and polyethylene; styrene-butadiene rubber; modified acrylonitrile rubber; or ethylene-acrylic acid copolymer. These binders may be used singly or in combination of two or more.

The dispersion medium used for forming a paste, in which the positive electrode active material, conductive material and binder are to be dispersed, may be an organic solvent, such as N-methyl-2-pyrrolidone, dimethylacetamide, cyclohexane, and methyl acetate; or water. The current collector may be an aluminum foil or a stainless steel foil.

Likewise, in forming a negative electrode for a lithium ion secondary battery, a negative electrode active material and a binder are mixed, and a dispersion medium is added to the resultant mixture, to form a paste. The paste is applied onto a surface of a negative electrode current collector, and dried, whereby a negative electrode precursor with a negative electrode material mixture layer formed thereon is obtained. The precursor is rolled, and then cut in a predetermined size, whereby a negative electrode for a lithium ion secondary battery is obtained.

The negative electrode active material is as described above. Examples of the binder and dispersion medium for a negative electrode are the same as those for a positive electrode, and they may be used singly or in combination of two or more. The current collector for a negative electrode may be a copper foil or a stainless steel foil.

The separator may be a porous thin film that can withstand the voltage at the positive electrode and negative electrode, and the non-aqueous electrolyte. Examples of such a porous thin film include: microporous film of thermoplastic resin, such as polyethylene and polypropylene; and nonwoven fabric of polypropylene.

The non-aqueous electrolyte can be prepared by dissolving a supporting salt in a solvent. Examples of the supporting salt include: fluorides, such as LiPF₆ and LiBF₄; and imides, such as LiN(CF₃SO₂)₂ and LiN(C₂F₅SO₂)₂. Examples of the solvent include: carbonate-based solvents, such as ethylene carbonate (EC), propylene carbonate, dimethyl carbonate (DMC), diethyl carbonate, ethyl methyl carbonate (EMC); lactone-based solvents, such as γ-butyrolactone and γ-valerolactone; ester-based solvents, such as ethyl acetate, propyl acetate, and ethyl propionate; and ether-based solvents, such as dimethoxyethane and 1,3-dioxolane. These solvents may be used singly or in combination of two or more. Alternatively, a gel electrolyte prepared by using a gelling agent such as polymethyl methacrylate. Further, in order to improve the reliability and durability of the battery, an additive such as vinylene carbonate, vinylethylene carbonate, or fluorinated propylene carbonate may be added.

The lithium ion battery may be of any shape and form such as a coin shape, a cylindrical shape, a prismatic shape, or a form of a laminate battery including an outer casing made of an aluminum laminate film.

### Embodiment 2

Next, Embodiment 2 of the present invention is described.

Embodiment 2 relates to a battery pack to which the method for evaluating the deterioration state of a lithium ion secondary battery as described as Embodiment 1 is applied.

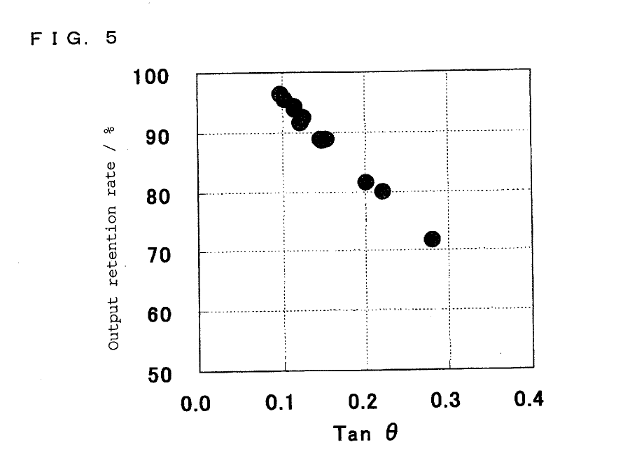

FIG. 4 is a function block diagram showing a schematic configuration of a battery pack according to Embodiment 2. As shown in the figure, a battery pack 40 includes a lithium ion secondary battery 12, a charging circuit 42 for charging the lithium ion secondary battery 12 with externally supplied power, a discharging circuit 44 for externally discharging power stored in the lithium ion secondary battery 12, and a controller 46 for controlling the charging circuit 42 and the discharging circuit 44. The battery pack 40 further includes an impedance meter 48 for measuring an impedance spectrum of the lithium ion secondary battery 12 by an AC impedance method, and an evaluation unit 50 for evaluating the deterioration state of the lithium ion secondary battery 12, on the basis of the measurement result of the impedance meter 48.

The lithium ion secondary battery 12 may comprise one or two or more lithium ion secondary batteries. The controller 46 may comprise: a microprocessor or central processing unit (CPU); a memory, such as a random access memory (RAM) or a read only memory (ROM); an input/output unit; and a communication module.

The impedance meter 48 has a configuration similar to that of the impedance meter 14 in Embodiment 1, and measures an impedance spectrum of the lithium ion secondary battery 12 in a way similarly to in Embodiment 1.

The evaluation unit 50 has a configuration similar to that of the computer 16 in Embodiment 1, and evaluates the deterioration state of the individual battery included in the lithium ion secondary battery 12. It is not essential, however, to draw a Cole-Cole plot from the measured impedance spectrum, as mentioned above. For example, if a frequency range corresponding to the arc-like portion 32a can be predicted, the deterioration state of the individual battery may be evaluated such that an impedance Z (=Z′−Z″j) at which the capacitive component becomes largest in the frequency range is determined, and evaluation is made on the basis of the components, Z′ and Z″, of the impedance Z. This is possible because the above impedance Z that gives the largest capacitive component coincides with the peak of the arc-like portion 32a.

Examples of the present invention are described below. It should be noted, however, that the present invention is not limited to the following Examples.

### Example 1

Lithium nickelate (LiNi_{0.75}Cu_{0.15}Al_{0.1}O₂) containing 15 atom % (atomic percent) cobalt and 10 atom % aluminum was used as a positive electrode active material. To 100 parts by weight of the positive electrode active material, 7 parts by weight of acetylene black serving as a conductive material and 5 parts by weight of polyvinylidene fluoride serving as a binder were added and mixed, and an appropriate amount of N-methyl-2-pyrrolidone was further added thereto, to give a paste. The paste was applied onto both surfaces of an aluminum foil and dried, to form a positive electrode precursor. The precursor was rolled, and then cut in a predetermined size, to which a positive electrode lead was welded. A positive electrode was thus prepared.

A graphite-type carbon material was used as a negative electrode active material. To 100 parts by weight of the negative electrode active material, 3 parts by weight of styrene-butadiene rubber serving as a binder was added and mixed, and an appropriate amount of water was further added thereto, to give a paste. The paste was applied onto both surfaces of a copper foil, which was then formed into a negative electrode in a way similar to that for forming a positive electrode. The positive electrode and the negative electrode were wound spirally with a separator made of polyethylene microporous film interposed therebetween, to form an electrode group.

The electrode group was inserted into a cylindrical iron case having an opening, and an electrolyte was injected into the case. The opening of the case was sealed with a sealing plate. The negative electrode lead was welded to the bottom of the case, and the positive electrode lead was welded to the sealing plate. The electrolyte has been prepared by dissolving LiPF₆ at a concentration of 1 mol/L in a mixed solvent of EC, DMC and EMC (1:1:1 volume ratio). In this way, ten cylindrical lithium ion secondary batteries were produced. The average initial charge/discharge capacity of the batteries was about 500 mAh.

In order to determine the initial DC internal resistance of the produced lithium ion secondary batteries (hereinafter referred to as “test batteries”), the test batteries in a 30% SOC were subjected to charge and discharge at three levels of constant current, and the discharge voltage measured 10 seconds after the start of discharge was recorded. From the relationship between the discharge current and the change in voltage (the slope of a straight line approximating the relationship therebetween), the DC internal resistance was calculated. The three levels of discharge current were set at 500 mA, 1000 mA and 2500 mA. The ambient temperature was set at 25° C. The average of the DC internal resistances of the ten test batteries measured as above was 71 mΩ. The value thus determined was referred to as an initial DC internal resistance.

Next, the impedance spectrum of the test batteries in a 30% SOC was measured at an ambient temperature of 25° C. within a frequency range from 0.1 to 30 Hz by an AC impedance method, using a potentio/galvanostat (Model No.: 1286) available from Solartron Inc. and a frequency response analyzer (Model No.: 1260) available from Solartron Inc.

### Example 2

One out of the ten test batteries was subjected to 1000 charge/discharge cycles at an ambient temperature of 20° C. in the following manner (charge/discharge cycle processing).

The test battery was charged at a constant current of 500 mA until the battery voltage reached 4.05 V, and subsequently charged at a constant voltage of 4.05 V until the charge current reached 5 mA or less. Upon termination of the constant-voltage charging, the test battery was allowed to stand for 30 minutes, and discharged at a constant current of 500 mA until the battery voltage dropped to 3.6 V. The above charge and discharge was regarded as one cycle, and upon completion of one charge/discharge cycle, the test battery was allowed to stand for 30 minutes and then subjected to the next charge/discharge cycle.

The impedance spectrum of the test battery having been subjected to the charge/discharge cycle processing consisting of 1000 cycles was measured using alternating current of a frequency range from 0.1 to 30 Hz. On the basis of the impedance spectrum thus measured, the above-mentioned angle θ and tan θ were calculated. Further, in order to determine an output retention rate of the test battery, the DC internal resistance was measured in the same manner as in Example 1. At this time, the SOC of the test battery was 30%, and the ambient temperature was set at 25° C.

In measuring the impedance spectrum, the above-mentioned potentio/galvanostat and frequency response analyzer were used. The output retention rate was calculated from the formula: (R2/R1)×100(%), where R1 is the DC internal resistance of the test battery, and R2 is the initial DC internal resistance, that is, the DC internal resistance of the test batteries measured in Example 1.

### Example 3

The angle θ, tan θ and output retention rate of the test battery were determined in the same manner as in Example 2, except that the number of cycles in the charge/discharge cycle processing was set to 2000 cycles.

### Example 4

The angle θ, tan θ and output retention rate of the test battery were determined in the same manner as in Example 2, except that the number of cycles in the charge/discharge cycle processing was set to 4000 cycles.

### Example 5

The angle θ, tan θ and output retention rate of the test battery were determined in the same manner as in Example 2, except that the ambient temperate was set to 50° C.

### Example 6

The angle θ, tan θ and output retention rate of the test battery were determined in the same manner as in Example 5, except that the number of cycles in the charge/discharge cycle processing was set to 2000 cycles.

### Example 7

The angle θ, tan θ and output retention rate of the test battery were determined in the same manner as in Example 5, except that the number of cycles in the charge/discharge cycle processing was set to 4000 cycles.

### Example 8

The angle θ, tan θ and output retention rate of the test battery were determined in the same manner as in Example 2, except that the ambient temperate was set to 60° C.

### Example 9

The angle θ, tan θ and output retention rate of the test battery were determined in the same manner as in Example 8, except that the number of cycles in the charge/discharge cycle processing was set to 2000 cycles.

### Example 10

The angle θ, tan θ and output retention rate of the test battery were determined in the same manner as in Example 8, except that the number of cycles in the charge/discharge cycle processing was set to 4000 cycles.

### Example 11

The areas of the positive and negative electrodes and the size of the case were increased, to produce three prismatic laminate lithium ion secondary batteries having a charge/discharge capacity of about 5 Ah, as test batteries. The initial DC internal resistance of each of the test batteries was measured in the same manner as in Example 1, except that the test battery was discharged at three levels of constant current: 5 A, 10 A and 25 A. As a result, the average of the DC internal resistances of the three test batteries was 3.25 mΩ. Next, one out of the three test batteries was subjected to the charge/discharge cycle processing consisting of 1000 cycles in the same manner as in Example 2, except that the constant-current charging and constant-current discharging were performed at 5 A. The angle θ and tan θ were determined in the same manner as in Example 2. Further, in order to determine an output retention rate of the test battery, the DC internal resistance of the test battery was measured in the same manner as in Example 1, except that the test battery was discharged at three levels of constant current: 5 A, 10 A and 25 A.

### Example 12

The angle θ, tan θ and output retention rate of the test battery were determined in the same manner as in Example 11, except that the number of cycles in the charge/discharge cycle processing was set to 2000 cycles.

### Example 13

The angle θ, tan θ and output retention rate of the test battery were determined in the same manner as in Example 11, except that the number of cycles in the charge/discharge cycle processing was set to 4000 cycles.

The results above are shown in Table 1 below. The (tan 0, output retention rate) points of Examples 2 to 13 are plotted on a graph, which is shown in FIG. 5.

TABLE 1

| | | Charge/discharge | | | | |
|---|---|---|---|---|---|---|
| | | cycle processing | | Output | | |
| | | Ambient | Number | retention | | |
| | Capacity | tempera- | of | rate | | |
| | (mAh) | ture | cycles | (%) | θ | tanθ |
| Example 1 | 500 | — | — | 100 | 5.15 | 0.090 |
| Example 2 | 500 | 25° C. | 1000 | 96.4 | 5.64 | 0.099 |
| Example 3 | 500 | 25° C. | 2000 | 94.3 | 6.68 | 0.117 |
| Example 4 | 500 | 25° C. | 4000 | 91.6 | 7.00 | 0.123 |
| Example 5 | 500 | 50° C. | 1000 | 92.5 | 7.25 | 0.127 |
| Example 6 | 500 | 50° C. | 2000 | 88.7 | 8.69 | 0.153 |
| Example 7 | 500 | 50° C. | 4000 | 81.4 | 11.43 | 0.202 |
| Example 8 | 500 | 60° C. | 1000 | 88.5 | 8.43 | 0.148 |
| Example 9 | 500 | 60° C. | 2000 | 79.8 | 12.50 | 0.222 |
| Example 10 | 500 | 60° C. | 4000 | 71.8 | 15.72 | 0.282 |
| Example 11 | 5000 | 25° C. | 1000 | 95.4 | 5.97 | 0.104 |
| Example 12 | 5000 | 25° C. | 2000 | 93.8 | 6.61 | 0.116 |
| Example 13 | 5000 | 25° C. | 4000 | 88.7 | 8.35 | 0.147 |

As shown in Table 1, the higher the ambient temperature was or the greater the number of cycles was, the lower the output retention rate of the test battery was. An approximate equation representing the relationship between the tan θ and the output retention rate in Examples 2 to 13 as plotted on the graph of FIG. 5 was determined by regression analysis, for example, by approximating the plots by the exponential function: Y=Aₑₓₚ(−BX). The obtained approximate equation was “Output retention rate=112.65×exp(−1.595×tanθ)”. The determination coefficient R² was 0.9954, which indicates the existence of a highly collated relationship between the tan θ and the output retention rate.

It was verified from the above results that even though the ambient temperatures and the battery capacities are different, the output retention rate of a lithium ion secondary battery can be easily determined by using the value of tan θ obtained by the AC impedance analysis in the frequency range from 0.1 to 30 Hz. Therefore, the deterioration state of the battery can be easily evaluated, simply by determining an approximate equation representing the relationship between the tan θ and the output retention rate beforehand and measuring the value of tan θ of the battery. Hence, the deterioration state of a lithium ion secondary battery can be evaluated for a short period of time in a simple and easy manner.

There is a case where no arc-like portion appears in AC impedance analysis in the frequency range from 0.1 to 30 Hz, when, for example, the battery is fresh or is not deteriorated so much. In this case, there is little or no deterioration in output, and therefore, the deterioration state can be judged as 0%.

### INDUSTRIAL APPLICABILITY

According to the present invention, it is possible to evaluate the deterioration state of a lithium ion secondary battery in a simple and easy manner, without taking a long time. Therefore, the deterioration evaluation method of the present invention is suitably applicable as a deterioration evaluation method of a lithium ion secondary battery for small-sized consumer electronics, and a lithium ion secondary battery for use in application requiring a large capacity and high output, such as electric vehicles and hybrid cars.

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

### REFERENCE SIGNS LIST

10 Deterioration evaluation apparatus
12 Lithium ion secondary battery
14 Impedance meter
16 Computer
20 AC oscillator
22 Ammeter
24 Voltmeter
26 Frequency response analyzer
40 Battery pack
42 Charging circuit
44 Discharging circuit
46 Controller
48 Impedance meter
50 Evaluation unit

1. A method for evaluating deterioration of a lithium ion secondary battery, the method comprising the steps of:
measuring an impedance spectrum of a lithium ion secondary battery, using alternating current of a predetermined frequency range,
determining coordinates of a peak of an arc-like portion, when the impedance spectrum is represented by a diagram including the arc-like portion on a complex plane defined by a resistive component axis and a capacitive component axis, and
evaluating a deterioration state of the lithium ion secondary battery, on the basis of the coordinates.

2. The method for evaluating deterioration of a lithium ion secondary battery in accordance with claim 1, wherein when the coordinates are denoted by (Z′, Z″), the deterioration state of the lithium ion secondary battery is evaluated on the basis of a ratio |Z″|/Z′.

3. The method for evaluating deterioration of a lithium ion secondary battery in accordance with claim 1, wherein
an angle θ between a straight line passing through the peak and the origin of the complex plane, and the resistive component axis is determined from the coordinates, and
the deterioration state of the lithium ion secondary battery is evaluated on the basis of the angle θ.

4. The method for evaluating deterioration of a lithium ion secondary battery in accordance with claim 3, wherein a tangent of the angle θ, tan θ, is calculated, and evaluating the deterioration state of the lithium ion secondary battery, on the basis of the tan θ.

5. The method for evaluating deterioration of a lithium ion secondary battery in accordance with claim 1, wherein the predetermined frequency range has a lower limit of fb and an upper limit of fu, the fb being 0.01≦fb≦0.5 Hz, and the fu being 10≦fu≦50 Hz.

6. The method for evaluating deterioration of a lithium ion secondary battery in accordance with claim 5, wherein the predetermined frequency range is from 0.1 to 30 Hz.

7. The method for evaluating deterioration of a lithium ion secondary battery in accordance with claim 1, wherein the lithium ion secondary battery includes a positive electrode including a composite oxide containing lithium and nickel.

8. The method for evaluating deterioration of a lithium ion secondary battery in accordance with claim 7, wherein at least one selected from the group consisting of Co, Al, Mn, Mg, Ca, Sr, Ti, Zr, V, Nb, Cr, Mo, Fe, Cu and B is added to the composite oxide.

9. The method for evaluating deterioration of a lithium ion secondary battery in accordance with claim 8, wherein Co and Al are added to the composite oxide.

10. The method for evaluating deterioration of a lithium ion secondary battery in accordance with claim 1, wherein the lithium ion secondary battery comprises a negative electrode including a carbon material.

11. A battery pack comprising
at least one lithium ion secondary battery,
a charging circuit for charging the lithium ion secondary battery with externally supplied power,
a discharging circuit for externally discharging power stored in the lithium ion secondary battery,
a controller for controlling the charging circuit and the discharging circuit,
a measurement unit for measuring an impedance spectrum of the lithium ion secondary battery by an alternating current impedance method, and
an evaluation unit for evaluating a deterioration state of the lithium ion secondary battery, on the basis of the measurement result of the measurement unit, wherein
the evaluation unit
determines coordinates of a peak of an arc-like portion, when the impedance spectrum is represented by a diagram including the arc-like portion on a complex plane defined by a resistive component axis and a capacitive component axis, and
evaluates the deterioration state of the lithium ion secondary battery on the basis of the coordinates.
